(19) United States
(12) Patent Application Publication
(10) Pub. No.: US 2006/0159277 A1
(43) Pub. Date: Jul. 20, 2006

(54) Distortion device

(76) Inventor: Masayuki Suda, Hamamatsu-shi (JP)

Correspondence Address: CHRISTIE, PARKER & HALE, LLP, PO BOX 7068, PASADENA, CA, 91109-7068, US

(21) Appl. No.: 11/328,785

(22) Filed: Jan. 9, 2006

(30) Foreign Application Priority Data
Jan. 14, 2005 (JP) 2005-007962

(51) Int. Cl. H03G 3/00

(52) U.S. Cl. 381/61

(57) ABSTRACT

The invention provides a distortion device that allows obtaining a comfortable distortion sound across a wide input level range with a simple construction. An output with a distortion, Y=AX+BSX² (here, A and B are constants, S is a value that becomes +1 or −1 according to a sign of the input X), is outputted from an input X. This calculating can be realized by an absolute value calculator (30) for calculating an absolute value of the input X, a multiplier (26) for multiplying the input X and an output from the absolute value calculator (30), a multiplier (27) for multiplying the input X by the constant A, a multiplier (28) for multiplying an output from the multiplier (26) by the constant B, and an adder (31) for adding an output from the multiplier (27) and an output from the multiplier (28)

### BACKGROUND OF THE INVENTION

1. Field of the Invention

The present invention relates to a distortion device and, more particularly, to a distortion device that allows obtaining a comfortable distortion sound across a wide input level range.

2. Description of the Related Art

A DSP (digital signal processor) of a musical sound generating apparatus has an effector function, and this effector function digitally carries out effect processings such as level control, time control, and frequency characteristics control to musical sound signals. The effect or functional so carries out a distortion processing to generate a distortion sound, and there are various distortion devices that carry out this processing.

For example, there is a distortion device for giving a distortion by outputting a maximum value or a minimum value that can be taken as an output to be outputted by applying an overflow limit by an overflow limiter when an input level exceeds a maximum value or a minimum value.

In addition, there is also a distortion device for giving a nonlinear input/output characteristic where an output changes in a manner being gradually compressed when an input level increases to a certain extent or more, so that the output is not suddenly clipped. By this distortion device, in brief, a nonlinear input/output characteristic becomes Y=ax+bX³ when an input is provided as X and an output is provided as Y, and constants a and b are set so that the output Y does not become 1 or more or −1 or less in a range of a maximum value ±1 of the input X. Herein, X³ is utilized as a lowest order that satisfies a condition that a characteristic becomes symmetrical between a positive side and a negative side of the input X, namely, one in which a nonlinear characteristic becomes symmetrical between a positive side and a negative side of the input X and a distortion can be given to the input X in a range as wide as possible.

Moreover, the present inventor has proposed a distortion device that allows obtaining a smooth and arbitrary nonlinear input/output characteristic in Patent Document 1. In this distortion device proposed in Patent Document 1, a nonlinear input/output characteristic becomes Y=A₁X¹+A₂X²+A₃X³+ . . . +AₙXⁿ when an input is provided as X, and an output, as Y, and coefficients, as A₁, A₂, A₃, . . . , Aₙ has been provided.

Patent Document 1: Japanese Patent Laid-open Publication No. H09-330082

However, in the distortion device using an overflow limiter, since an output is suddenly clipped when an input level exceeds a maximum value or a minimum value, a problem occurs such that an aliasing noise of a musical sound, which is a feature of a digital processing, is generated, and this results in a discomfort sound.

Moreover, in the distortion device utilizing a nonlinear input/output characteristic that becomes Y=aX+bX³, an output gradually changes when an input level reaches a certain extent or more, and no sudden clipping is carried out, a discomfort sound including an aliasing noise can be suppressed from being generated. The nonlinear characteristic has something in common with a nonlinear input/output characteristic of an analog effector using a semiconductor or a vacuum-tube amplifier. However, in the distortion device using a nonlinear input/output characteristic utilizing X³, a region where the input/output characteristic is nearly linear is wide. As a result, a problem exists such that an input level where a satisfactory distortion sound can be obtained is limited to a narrow range. In other words, an output waveform is hardly distorted at a relatively small input level, and where an appropriate distortion can be obtained as a distortion sound is limited to a narrow input level range. In addition, when the input level further increases beyond the range, clipping occurs at a point in time of input to generate a discomfort distortion sound. In general, the more a function that is great in the power of an input X is used, the wider the nearly linear region becomes, thus the input level where a satisfactory distortion sound can be obtained is narrowed.

In order to avoid this clipping in the output waveform, it can also be considered to provide an input level adjusting circuit such as an AGC (automatic gain controller) or a compressor before a distortion circuit in a distortion device, however, a problem exists such that this results in a large circuit scale as a whole.

Moreover, the distortion device proposed in Patent Document 1 requires a large number of multipliers and adders to obtain a better distortion effect and therefore has a large circuit scale.

### SUMMARY OF THE INVENTION

It is an object of the present invention to solve the problems and provide a distortion device that allows obtaining a comfortable distortion sound across a wide input level range with a simple construction.

In order to accomplish the object, the first feature of this invention is that a distortion device for outputting a musical sound signal with a distortion with respect to an input musical sound signal, comprises where an input is provided as X, and an output, as Y, a calculating means for calculating according to a nonlinear input/output characteristic to become Y=AX+BSX², when A and B are constants, S is a value that becomes +1 or −1 according to a sign of the input X.

Also, the second feature of this invention is that the distortion device, wherein the calculating means comprises an absolute value calculator for calculating an absolute value of the input X, a multiplier for multiplying the input X and an output from the absolute value calculator, and a calculating unit for multiplying the input X by the constant A, multiplying an output from the multiplier by the constant B, and adding both.

Also, the third feature of this invention is that the distortion device, wherein the calculating means comprises a square calculator for calculating a square of the input X, a register for storing a value of +1 or −1 according to a sign of the input X, a multiplier for multiplying an output from the square calculator and the value stored in the register, and a calculating unit for multiplying the input X by the constant A, multiplying an output from the multiplier by the constant B, and adding both.

According to the present invention, since the nonlinear input/output characteristic utilizing X² is used, a satisfactory distortion sound can be obtained from a relatively small input level across a wide input level range with a simple construction, which makes it possible to increase a margin of the input level until an output waveform is clipped. In addition, although a characteristic becomes asymmetrical between a positive side and a negative side of the input X when X² is utilized as it is, since a sign of input is saved at X² in the present invention, the characteristic can be made symmetrical between the positive side and negative side of the input.

### BRIEF DESCRIPTION OF THE DRAWINGS

FIG. 1 is a block diagram showing a musical sound generating apparatus to which the present invention has been applied.

FIG. 2 is a functional block diagram showing an embodiment of a distortion device according to the present invention.

FIG. 3 is a functional block diagram showing another embodiment of a distortion device according to the present invention.

FIG. 4 is a characteristics diagram showing examples of nonlinear input/output characteristics.

FIG. 5 is a characteristics diagram showing characteristics when small-level parts were matched in the nonlinear input/output characteristics of FIG. 4.

### DETAILED DESCRIPTION OF THE PREFERRED EMBODIMENT

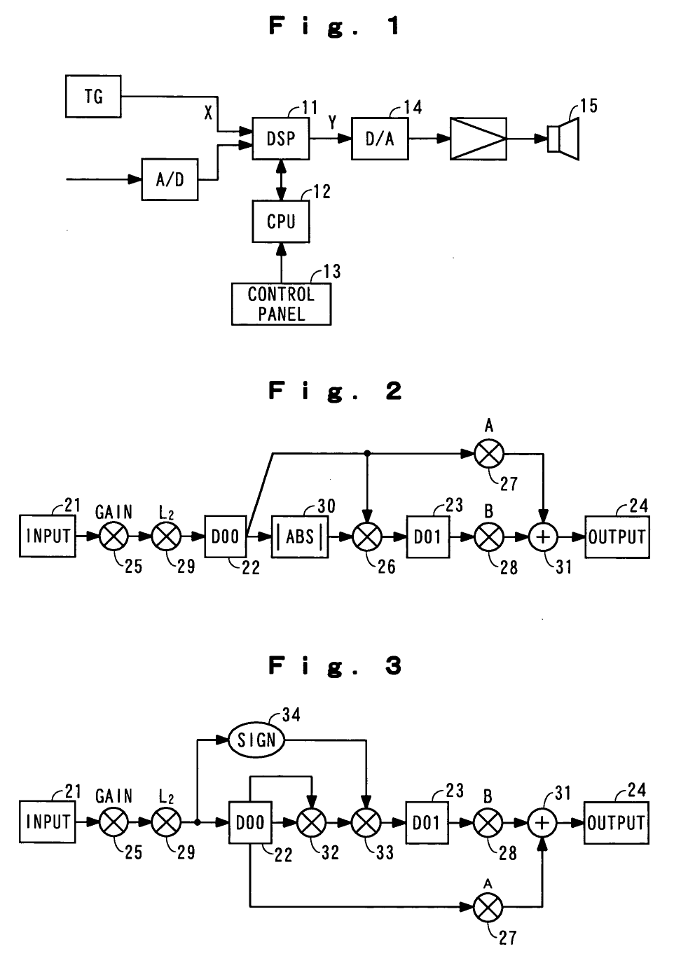

Hereinafter, the present invention will be described in detail with reference to the drawings. FIG. 1 is a block diagram showing a musical sound generating apparatus to which the present invention has been applied. An input X such as a digital signal sent out from a tone generator (TG) or a digital signal obtained as a result of an A/D conversion of an analog signal outputted from another unit is inputted into a DSP 11. The DSP 11 can function also as an effector while storing a program inputted from a CPU 12, and this sends out the input X after applying various digital processings based on an instruction from a control panel 13 or as it is as an output Y.

The DSP 11 has a function of a distortion device for outputting a distortion sound by intentionally distorting an output Y with respect to an input X. The distortion device provides a nonlinear input/output characteristic to become Y=AX+BSX² according to the present invention. Here, A and B are constants, S is a value that becomes +1 or −1 according to a sign of the input X. In addition, the input X and output Y are −1≦X≦+1 and −1≦Y≦+1.

The output from the DSP 11 is converted to an analog signal by a D/A converter 14, and is, after amplification by an amplifier, sent out to a speaker 15. The speaker 15 outputs a musical sound externally in accordance with the input analog signal.

In this manner, by using a nonlinear input/output characteristic utilizing X², a region having an almost linear relationship of input/output can be narrowed. In addition, by using a square signal with a sign of an input X, since a distortion can be given similarly between a positive side and a negative side of the input X, a natural and satisfactory distortion sound can be obtained across an input level range as wide as possible. Moreover, unlike giving a distortion by using an input/output characteristic that indicates nonlinearity only in the vicinity of the upper limit of the input X, an appropriate distortion can be given at a relatively small input level, therefore, a margin of the input level until an output waveform is clipped can be increased.

FIG. 2 is a functional block diagram showing an embodiment of a distortion device according to the present invention. A distortion device of the present embodiment comprises registers 21 to 24 for storing data, multipliers 25 to 28, a shifter 29, an absolute value calculator 30, and an adder 31.

An input digital signal is first stored in the input register (INPUT) 21, and the signal read out therefrom is inputted into the multiplier 25 to multiply the same by a coefficient (GAIN) equal to or less than 1. Next, an output from the multiplier 25 is inputted into the shifter 29 to shift bits. The shifter 29 shifts bits of the input to increase the level of the bits by four, for example. The multiplier 25 and shifter 29 are provided for adjusting the input level.

Next, an output from the shifter 29 is stored in the register 22, and an output read out from the register 22 is inputted into the absolute value calculator 30 to calculate an absolute value thereof. Next, an output from the absolute value calculator 30 and an output from the register 23 corresponding thereto are inputted into the multiplier 26 to multiply both, and the result of multiplication is stored in the register 23. Where an input whose level has been adjusted by the multiplier 25 and shifter 29 is provided as X and a value that becomes +1 or −1 according to a sign (pulse/minus) of the input X is provided as S, a signal to be stored in the register 23 results in SX², which is X² with a sign.

Next, data read out from the register 22 is inputted into the multiplier 27 to multiply the same by a coefficient A, and data read out from the register 23 is inputted into the multiplier 28 to multiply the same by a coefficient B. Next, an output from the multiplier 27 and an output from the multiplier 28 are inputted into the adder 31, and an output from the adder 31 is stored in the output register (OUTPUT) 24.

Here, a signal Y to be stored in the output register (OUTPUT) 24 results in SX² (here, S is a value that becomes +1 when the input X is positive, and when negative, −1). Namely, a nonlinear input/output characteristic of Y=AX+BSX² can be obtained by a simple construction for carrying out the above series of processings mentioned above.

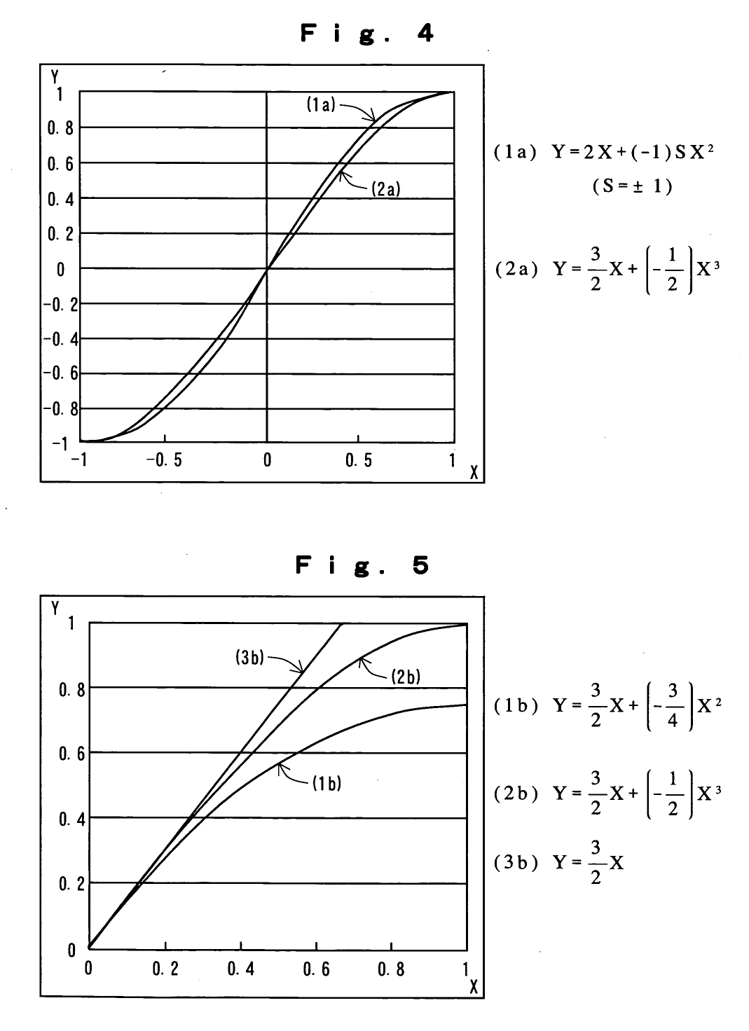

FIG. 3 is a functional block diagram showing another embodiment of a distortion device according to the present invention. In FIG. 3, identical symbols are used for parts identical or equivalent to those of FIG. 2. A distortion device of the present embodiment comprises registers 21 to 24 for storing data, multipliers 25, 27, 28, 32, and 33, a shifter 29, an adder 31, and a sign register 34.

In the present embodiment, since processings up to the shifter 29 are the same as those of FIG. 2, description thereof is omitted. According to the present embodiment, an output from the shifter 29 is stored in the register 22, and two outputs read out from the register 22 are inputted into the multiplier 32 and mutually multiplied to obtain X². However, since a sign of the input X is lost in this condition, the sign register 34 is separately provided to extract and store a sign of the input X. A value to be stored in the sign register 34 is +1 when the input X is positive, and when negative, −1.

Next, an output from the multiplier 32 and an output from the sign register 34 are inputted into the multiplier 33 to multiply both, and the result of multiplication is stored in the register 23. Where an input whose level has been adjusted by the multiplier 25 and shifter 29 is provided as X and a value that becomes +1 or −1 according to a sign (pulse/minus) of the input X is provided as S, a signal to be stored in the register 23 results in SX², which is the same as in the embodiment of FIG. 2.

Next, data read out from the register 22 is inputted into the multiplier 27 to multiply the same by a coefficient A, and data read out from the register 23 is inputted into the multiplier 28 to multiply the same by a coefficient B. Next, an output from the multiplier 27 and an output from the multiplier 28 are inputted into the adder 31, and an output from the adder 31 is stored in the output register (OUTPUT) 24. Through the series of processings mentioned above as well, a nonlinear input/output characteristic to be Y=AX+BSX² can be obtained by a simple construction.

FIG. 4 shows examples of nonlinear input/output characteristics, wherein (1a) is a characteristic when a second power (Y=2X+(−1)SX²) is used, and (2a) is a characteristic when a third power (Y=(3/2)X+(−1/2) X³) is used. In addition, constants A and B in these cases are determined on a condition that the characteristics pass through a point (X=1, Y=1) and slopes of the curves become 0 at X=1. FIG. 5 shows characteristics (1b) and (2b) when small-input-level parts of nonlinear characteristics of the characteristic (1a) and characteristic (2a) are adjusted in the part where the input X is positive in FIG. 4, namely, when slopes of the characteristic curves of both at X=0 are equalized. Thereby, an overall difference between curvatures (degrees of curving) of the characteristic (1b) and characteristic (2b) can be easily grasped. In FIG. 5, a linear characteristic (3b) of a straight line with the same slope is also shown. In FIG. 5, the characteristic (1b) becomes Y=(3/2)X+(−3/4)SX²), the characteristic (2b) becomes Y=(3/2)X+(−1/2)SX³), and the characteristic (3b) becomes Y=(3/2)X.

It can be understood from FIG. 4 and FIG. 5 that, since the curvature as a whole is greater when the second power is used than when the third power is used, a distortion can be given at a smaller input level, and a distortion effect can be obtained at a wider input level range.

Moreover, as can be understood from FIG. 5, in the characteristic (2b), a distortion cannot be sensed unless the input level is adjusted to approximately 0.6 or more. However, when the input level is adjusted to approximately 0.6, the input level becomes 1 or more to cause clipping when two tones or three tones are simultaneously played, for example. In other words, a dynamic range of the input level cannot be largely secured.

In contrast thereto, at the characteristic (1b), it is sufficient to adjust the input level to approximately 0.3 in order to obtain the same distortion rate as that of the input level of approximately 0.6 of the characteristic (2b), and since there is still a considerable allowance for the input level, no clipping occurs even when two tones or three tones are simultaneously played, for example. Accordingly, in this case, since adjusting the input level to approximately 0.3 makes it possible to sense an appropriate distortion and to largely secure a dynamic range of the input level, a comfortable distortion sound can be obtained at a widely ranged input level.

What is claimed is:

1. A distortion device for outputting a musical sound signal with a distortion with respect to an input musical sound signal, comprising:
where an input is provided as X, and an output, as Y,
a calculating means for calculating according to a nonlinear input/output characteristic to become Y=AX+BSX², when A and B are constants, S is a value that becomes +1 or −1 according to a sign of the input X.

2. The distortion device according to in claim 1, wherein
the calculating means comprises an absolute value calculator for calculating an absolute value of the input X, a multiplier for multiplying the input X and an output from the absolute value calculator, and a calculating unit for multiplying the input X by the constant A, multiplying an output from the multiplier by the constant B, and adding both.

3. The distortion device according to claim 1, wherein
the calculating means comprises a square calculator for calculating a square of the input X, a register for storing a value of +1 or −1 according to a sign of the input X, a multiplier for multiplying an output from the square calculator and the value stored in the register, and a calculating unit for multiplying the input X by the constant A, multiplying an output from the multiplier by the constant B, and adding both.
